(19) United States
(12) Patent Application Publication
(10) Pub. No.: US 2018/0174850 A1
(43) Pub. Date: Jun. 21, 2018

(54) PRODUCTION METHOD FOR SEMICONDUCTOR DEVICE ELECTRODE

(71) Applicants: TANAKA KIKINZOKU KOGYO K.K., Tokyo (JP); TOKYO INSTITUTE OF TECHNOLOGY, Tokyo (JP)

(72) Inventors: Shunichiro OHMI, Meguro-ku, Tokyo (JP); Yasushi MASAHIRO, Chiyoda-ku, Tokyo (JP)

(21) Appl. No.: 15/574,942

(22) PCT Filed: Jun. 21, 2016
(86) PCT No.: PCT/JP2016/068327

§ 371 Date: Nov. 17, 2017

(30) Foreign Application Priority Data
Jun. 26, 2015 (JP) 2015-128775

(51) Int. Cl. H01L 21/285; C23C 14/00; C23C 14/06; C23C 14/16; C23C 14/58; H01L 21/768; H01L 29/45

(52) U.S. Cl. CPC H01L 21/28518; C23C 14/0036; C23C 14/0641; H01L 29/456; C23C 14/5873; H01L 21/2855; H01L 21/76889; C23C 14/165

(57) ABSTRACT

The present invention provides a method for producing a semiconductor device electrode, the method including the steps of: forming a first thin-film including a first metal on a substrate containing Si; forming a second thin-film including a compound of a second metal on the first thin-film; and performing a heat treatment to form an electrode including a silicide of the first metal, and is characterized in that hafnium (Hf) is applied as the second metal. HfN, HfW, HfB or the like is suitable as the compound of the second metal. The present invention can effectively suppress oxidation of a metal thin-film to be silicified, in formation of a silicide electrode on a silicon substrate.

### TECHNICAL FIELD

The present invention relates to a method for producing a silicide electrode in a semiconductor device such as a MOSFET.

### BACKGROUND ART

In a semiconductor device such as a MOSFET, a gate electrode and a source/drain region are formed on a silicon substrate, a silicide electrode is then formed on the gate and source/drain region for formation of a metal/semiconductor junction. The silicide electrode is formed in the following manner: a metal thin-film is deposited on the substrate by a sputtering method or the like, and a heat treatment is performed, so that silicon is diffused into the metal thin-film to silicify the metal thin-film. As for the configuration of the silicide electrode, titanium silicide (TiSi₂) and cobalt silicide (CoSi₂) have been generally known previously. For attaining miniaturization and thinning of devices, nickel silicide (NiSi) is used as a silicide with reduced Si consumption in which the junction depth in a source/drain region can be made extremely small. Further, platinum silicide (PtSi) having no risk of phase transition in a heat treatment in silicidation is also expected.

As described above, it is necessary that a thin-film of a metal to be silicified, such as Ni, be formed, and heat treated in production of a silicide electrode. The heat treatment temperature is about 300° C. or higher and 600° C. or lower though it depends on a metal. Thus, it is concerned that an insulating film is formed due to oxidation of the metal as silicidation progresses in the heat treatment process. In addition, oxidation of the metal may deteriorate the surface structure of the silicide electrode, leading to an increase in electric resistance.

For suppressing formation of an insulating film and deterioration of the structure of a silicide film during production of a silicide electrode, a method has been heretofore proposed in which on a thin-film of a metal (first metal) to be silicified, a film of a compound of other metal (second metal) is formed before heat treatment to suppress oxidation of the first metal (hereinafter, the film of a compound of the second metal is sometimes referred to as a Cap layer (cap layer)). It has been heretofore reported that titanium nitride (TiN), titanium carbide (TiC) or the like is useful as the metal compound that forms the Cap layer.

### RELATED ART DOCUMENT

### Patent Documents

### Patent Document 1: JP H7-38104 A

### Patent Document 2: JP H9-153616 A

### SUMMARY OF THE INVENTION

### Problems to be Solved by the Invention

Attainment of miniaturization and thinning has been more increasingly demanded in design of semiconductor devices in recent years, and it is necessary for silicide electrodes to follow this tendency. Thus, an attempt has been made to reduce the thickness of a first metal and narrow a contact area, and in this situation, improvement of the barrier ability of a cap layer is necessary for reducing the resistance of the silicide electrode and flattening the silicide electrode.

The present invention has been made against the background described above, and provides a method for forming a silicide electrode on a silicon substrate, the method being able to more effectively suppress formation of an insulating film due to oxidation of a first metal thin-film formed in silicidation, and a change in surface structure of the silicide electrode.

### Means for Solving the Problems

For solving the problems described above, the present inventors conducted studies on a constituent material of a Cap layer for protecting a first metal. Resultantly, the present inventors have found that hafnium (Hf) is particularly effective as a second metal, leading to the present invention.

That is, the present invention provides a method for producing a semiconductor device electrode including: forming a first thin-film including a first metal on a substrate containing Si; forming a second thin-film including a compound of a second metal on the first thin-film; and performing a heat treatment to form an electrode including a silicide of the first metal, the second metal being hafnium (Hf). Hereinafter, the method for producing a semiconductor device electrode according to the present invention will be described.

The thin-film of the first metal for producing a silicide electrode is formed on a Si section of the substrate. In a MOSFET to which the silicide electrode is assumed to be applied, normally a Si substrate is used as a substrate of a device, and for forming a source/drain, a region corresponding to the source/drain is doped with a dopant to form a diffusion layer. The first thin-film is formed on the source/drain region. The diffusion layer is formed by a conventional general method. Along with formation of the source/drain region, formation of a gate electrode is performed in accordance with a conventional art.

The first metal that forms the silicide electrode is preferably any of Ti, Co, Ni and Pt, or an alloy of these metals. As described above, versatility of Ti silicide and Co silicide, Ni silicide property for making the junction depth extremely small, and favorable heat resistance of Pt silicide are considered. A silicide of an alloy of Pt and Hf (PtHf) also provides a useful silicide electrode in that the silicide has a work function in the vicinity of midgap with respect to Si (n-Si or p-Si) that forms the substrate, so that the barrier height can be decreased.

The thickness of the first thin-film is determined according to a junction depth etc. required for the device, and has nothing to do with suppression of oxidation of the first metal which is a subject matter of the present invention. Accordingly, the thickness of the first thin-film is not limited by the present application.

The method for forming the thin-film of the first metal is not particularly limited, and either a physical method such as a sputtering method or a vacuum vapor deposition method or a chemical method such as a chemical vapor deposition method (CVD method) can be applied, but a sputtering method is preferable. The type of sputtering in formation of the thin-film is not particularly limited, and the thin-film is formed by magnetron sputtering, ion beam sputtering, electron cyclotron resonance (ECR) sputtering, mirrortron sputtering, radio frequency (RF) sputtering, direct-current (DC) sputtering or the like.

After the first thin-film is formed, a thin-film of a compound of a second metal is formed on the first thin-film. In the present invention, the second metal is hafnium (Hf). According to the present inventors, Hf has such a property that in formation of a compound, an amorphous phase is relatively easily developed and maintained, and a structural change by crystallization hardly occurs even when heat is applied. Thus, as compared to TiN or the like that has been heretofore used for a Cap layer, a Hf compound has higher heat resistance, and more excellent barrier performance for the first thin-film.

Specific examples of the Hf compound may include HfN, HfW and HfB. Among these Hf compounds, HfN capable of forming high amorphous phase developing property and favorable heat resistance is more preferable. HfN also has an advantage that it has favorable etching property, and thus a removal step after silicidation can be simplified.

The thickness of the Hf compound is preferably 10 nm or more and 20 nm or less. When the thickness is in this range, high oxidation resistance is exhibited, and crystallization hardly occurs.

As for the first thin-film, the method for forming the Hf compound thin-film is not particularly limited, but a sputtering method is preferable. In view of that a nitride film is formed, reactive sputtering is employed.

After the Hf compound thin-film as a second thin-film, the first metal is silicified by heat treatment (annealing). The heat treatment is performed preferably at 400° C. or higher and 600° C. or lower. When the heat treatment temperature is in this range, the resistivity can be reduced. The heat treatment atmosphere is preferably a non-oxidizing atmosphere (vacuum atmosphere, inert gas atmosphere or reducing atmosphere). Preferably, the heat treatment is performed using a high-speed heat treatment apparatus.

Preferably, the method includes a step of removing the second thin-film after annealing. This is because the Hf compound thin-film as the second thin-film is intended to block the first metal in silicidation by annealing, and therefore the role of the Hf compound thin-film is finished when annealing is completed. Preferably, removal of the Hf compound thin-film is performed by wet etching. Examples of the preferred etchant include diluted hydrofluoric acid and buffer hydrofluoric acid.

Preferably, an unreacted first metal that is not silicified after annealing is removed along with removal of the Hf compound thin-film. The unreacted first metal is removed by etching. The etchant is selected according to the kind of the first metal, and examples of the etchant include diluted hydrofluoric acid, aqua regia and sulfuric acid.

Through the above steps, a silicide electrode of the first metal is formed on the substrate. In production of a semiconductor device, subsequent steps conform to a conventional process.

### Advantageous Effects of the Invention

The present invention is intended to optimize a constituent material of a compound of a second metal (Cap layer) which suppresses oxidation of a first metal thin-film to be silicified in production of a silicide electrode of a semiconductor device. A Hf compound to be employed in the present invention has more excellent barrier performance as compared to a conventional art, and is applicable even to production of a miniaturized and thinned silicide film.

### BRIEF DESCRIPTION OF THE DRAWINGS

FIG. 1 illustrates a process for producing a sample for an evaluation test in a first embodiment.

FIG. 2 shows a photograph of the surface structure of a silicide (PtSi) electrode produced in the first embodiment.

FIG. 3 illustrates a process for producing a CBKR structure produced in a second embodiment.

### DESCRIPTION OF EMBODIMENT

Hereinafter, an embodiment of the present invention will be described.

### First Embodiment

In this embodiment, the surface structure of a silicide electrode after annealing was examined as a preliminary test for the case where Pt was deposited as a first metal for forming Pt silicide on a Si substrate, and a HfN thin-film was formed on the Pt and the case where a HfN thin-film was not formed on the Pt deposited as described above.

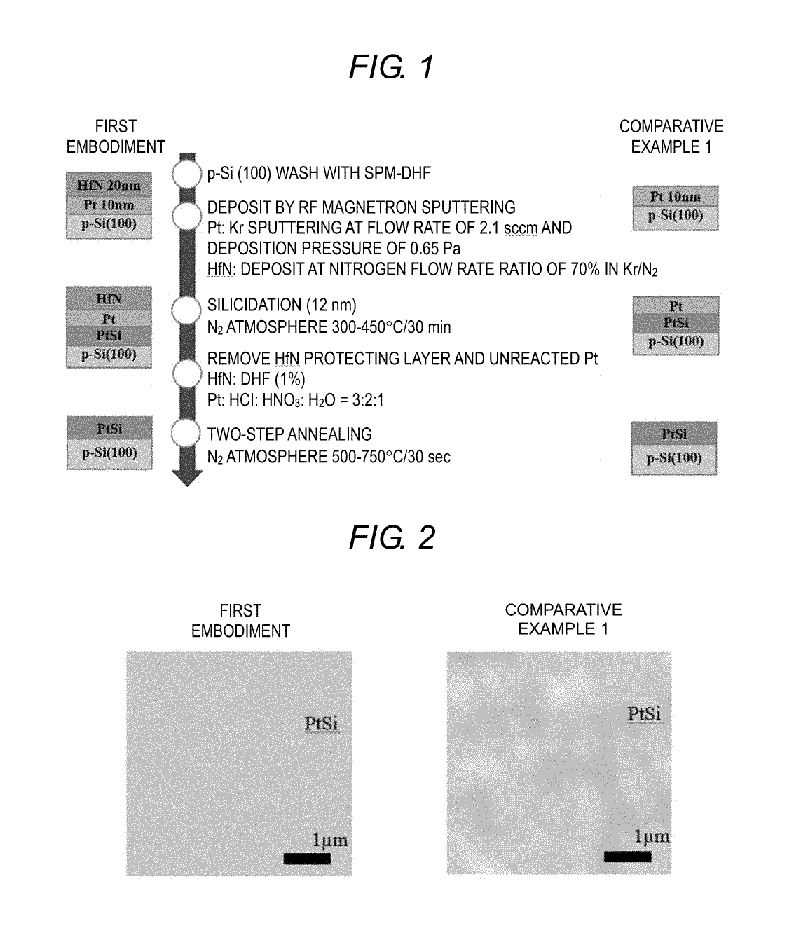

FIG. 1 shows a process of a comparison test according to this embodiment. In this embodiment, a Si substrate (p-Si(100)) was provided, and chemically cleaned, and a Pt thin-film was then deposited in a thickness of 10 nm by a sputtering method.

In this embodiment, a HfN thin-film was formed on the Pt thin-film. The HfN thin-film was deposited (thickness: 20 nm) by reactive sputtering with Kr/N2 as a deposition atmosphere using a Hf target. In a comparative example, the sample was subjected to silicidation without forming the HfN thin-film.

Next, silicidation was performed by heat treatment. As conditions for silicidation, the treatment temperature was 450° C., the treatment atmosphere was a nitrogen gas, and the treatment time was 30 minutes.

After formation of Pt silicide, the HfN film and unreacted Pt were removed by etching to obtain a device. First, HfN was removed with diluted hydrofluoric acid (1%), and unreacted Pt was then removed with diluted aqua regia (HCl:HNO₃: H₂O=3:2:1, temperature: 40° C.). Thereafter, a heat treatment was performed in a nitrogen gas as a treatment atmosphere at 750° C. for 30 seconds.

For the Si substrate with a silicide film formed as described above, the surface structure of the silicide film was observed with a SEM. FIG. 2 is a photograph showing the result of the observation. As is apparent from FIG. 2, the silicide film of the comparative example in which a Cap layer including HfN was not applied had irregularities formed on a surface, and was rated as having structural defects. On the other hand, the silicide film of this embodiment had no such structural defects observed. It was confirmed that in annealing for silicidation, the barrier effect by the HfN thin-film effectively acted.

For the silicide alloy film, a root mean square (RMS) roughness was measured (scan width: 3 μm) by an AFM (atomic force microscope), and the result showed that the Pt silicide alloy film of this embodiment in which the Cap layer was applied had a RMS of 2.26 nm. On the other hand, the Pt silicide film of the comparative example in which the Cap layer was not applied had a RMS of 3.12 nm.

### Second Embodiment

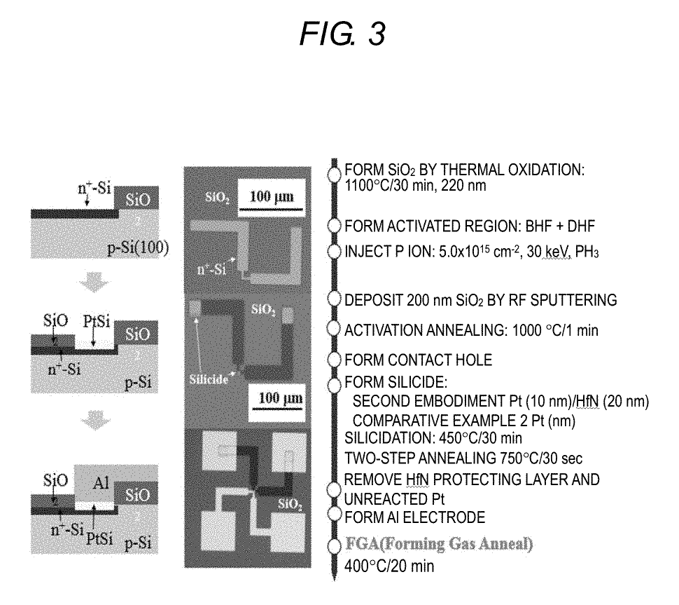

Here, for reproduction and evaluation of the effect on an actual process for producing a semiconductor device element regarding usefulness of the HfN thin-film, contact resistance (interface contact resistance) in a four-terminal Kelvin test structure was evaluated by a cross-bridge Kelvin resistance method (hereinafter, referred to as CBKR). FIG. 3 schematically illustrates a process for forming a CBKR structure while applying the HfN thin-film. In this evaluation test, a change in interface resistance in the case of performing annealing with a forming gas (N₂/4.9% H₂) (Forming Gas Anneal: FGA) after formation of the CBKR structure was also examined. Table 1 shows results of measuring interface resistance between the silicide electrode and the Al electrode by a BKR method.

TABLE 1

Contact resistance value

| | After production | |
|---|---|---|
| | (before FGA) | After FGA |
| Second Embodiment | 3.1 × 10⁻⁶ Ω cm² | 4.8 × 10⁻⁷ Ω cm² |
| Comparative Example 2 | 3.5 × 10⁻⁵ Ω cm² | 4.9 × 10⁻⁶ Ω cm² |

From Table 1, it can be confirmed that when the HfN thin-film is applied as a Cap layer in production of a silicide electrode, contact resistance can be reduced. In connection with FGA, FGA is essentially an operation for improving electrical contact between Al and the silicide electrode to improve interface resistance. It has been confirmed that when a Cap layer including a HfN thin-film is applied, the action of FGA can be maintained, and by the HfN thin-film and the Cap layer, contact resistance can be considerably reduced.

### INDUSTRIAL APPLICABILITY

According to the present invention, in production of a silicide electrode, one that is superior in quality to conventional products can be produced. The method according to the present invention is useful as a process for producing a silicide electrode in various kinds of semiconductor devices such as a MOSFET.

1. A method for producing a semiconductor device electrode comprising the steps of:
forming a first thin-film including a first metal on a substrate containing Si;
forming a second thin-film including a compound of a second metal on the first thin-film; and
performing a heat treatment to form an electrode including a silicide of the first metal, wherein hafnium (Hf) is to be applied as the second metal.

2. The method for producing a semiconductor device electrode according to claim 1, wherein the compound of the second metal is HfN, HfW or HfB.

3. The method for producing a semiconductor device electrode according to claim 1, wherein the first metal is any of Ti, Co, Ni and Pt, or an alloy of these metals.

4. The method for producing a semiconductor device electrode according to claim 1, wherein the method includes a step of removing the second thin-film after the heat treatment.

5. The method for producing a semiconductor device electrode according to claim 2, wherein the first metal is any of Ti, Co, Ni and Pt, or an alloy of these metals.

6. The method for producing a semiconductor device electrode according to claim 2, wherein the method includes a step of removing the second thin-film after the heat treatment.

7. The method for producing a semiconductor device electrode according to claim 3, wherein the method includes a step of removing the second thin-film after the heat treatment.
